(19) United States
(12) Patent Application Publication
(10) Pub. No.: US 2018/0013384 A1
(43) Pub. Date: Jan. 11, 2018

(54) TEMPERATURE-COMPENSATED CRYSTAL OSCILLATOR BASED ON ANALOG CIRCUIT

(71) Applicant: UNIVERSITY OF ELECTRONIC SCIENCE AND TECHNOLOGY OF CHINA, Chengdu (CN)

(72) Inventors: Feng TAN, Chengdu (CN); Duyu QIU, Chengdu (CN); Peng YE, Chengdu (CN); Jiquan CHEN, Chengdu (CN); Lianping GUO, Chengdu (CN); Hao ZENG, Chengdu (CN); Shuo ZHANG, Chengdu (CN); Ke TANG, Chengdu (CN)

(73) Assignee: UNIVERSITY OF ELECTRONIC SCIENCE AND TECHNOLOGY OF CHINA, Chengdu (CN)

(21) Appl. No.: 15/711,430

(22) Filed: Sep. 21, 2017

(30) Foreign Application Priority Data
May 17, 2017 (CN) 201710348894.7

(51) Int. Cl. H03B 5/04; H03L 1/02; H03B 5/36

(52) U.S. Cl. CPC H03B 5/04; H03B 5/366; H03L 1/02

(57) ABSTRACT

Disclosed is a temperature-compensated crystal oscillator based on analog circuit; a closed-loop compensation architecture determines the temperature compensation of a crystal oscillator. The power splitter divides the VCXO's current output signal with frequency f=f₀+Δf into two signals, one signal to output of the TCXO and the other signal is sent to an analog frequency-voltage conversion circuit. According to the frequency of the VCXO's current output signal, the analog frequency-voltage conversion circuit produces a voltage signal V(T), which corresponds to current ambient temperature. The difference between V(T) and a reference voltage signal V_{ref} is produced and amplified to obtain a compensation voltage signal ΔV through a voltage matching circuit. ΔV is smoothed by a filter, then sent to the voltage control terminal of the VCXO to make the VCXO generate a stable signal with desired frequency f₀, to compensate the frequency of the VCXO's output signal when the ambient temperature is changed.

### FIELD OF THE INVENTION

This application claims priority under the Paris Convention to Chinese Patent Application No. 201710348894.7, Filed May 17, 2017, the entirety of which is hereby incorporated by reference for all purposes as if fully set forth herein.

The present invention relates to the field of crystal oscillator, more particularly to a temperature-compensated crystal oscillator based on analog circuit.

### BACKGROUND OF THE INVENTION

Temperature-Compensated Xtal (crystal) Oscillator (hereinafter referred as TCXO) is a kind of crystal oscillator which can work in a wide temperature range and keep the output frequency of the crystal oscillator within a certain accuracy range (10⁻⁶˜10⁻⁷ orders of magnitude) through a certain compensation. It has a characteristic of low power consumption, working upon power-up, high stability and so on. Therefore it has been widely used in various communications, navigation, radar, satellite positioning system, mobile communication, program-controlled telephone switch and various electronic measuring instruments.

The temperature-compensated crystal oscillator in prior art is essentially a Voltage-Controlled Xtal (crystal) Oscillator (hereinafter referred as VCXO) with a temperature compensated network which produces a temperature-dependent compensation voltage. The key component in the uncompensated voltage-controlled crystal oscillator is a AT-cut quartz crystal, which temperature characteristic curve is approximately a cubic curve, and the cubic curve can be expressed as:

f(T)=a₃(T−T₀)³+a₁(T−T₀)+a₀ (1)

Where a₃ is the coefficient of cubic term, a₁ is the coefficient of linear term, a₀ is the oscillating frequency at a reference temperature T₀, T is the temperature of the location the AT-cut quartz crystal is at.

The frequency linear gain characteristics of the VCXO in prior art can be approximately expressed as:

f(VC)=−G(VC−₀)+f₀ (2)

where G is the gain of the VCXO, VC is the control voltage of the VCXO, VC₀ is the input voltage of the voltage control terminal of the VCXO, f₀ is the oscillating frequency when the input voltage is VC₀.

Then, the equation of the compensation voltage of the crystal temperature characteristic can be expressed as:

VC(T)=A₃(T−T₀)³+A₁(T−T₀)+A₀ (3)

Where A₃=a₃/G, A₁=a₁/G, A₀ is a compensation voltage when the temperature T is T₀.

In order to implement equation (3), it is necessary to generate a temperature compensation voltage applied to the VCXO for temperature compensation to counteract the frequency temperature characteristic, thereby obtaining a stable frequency output within a wide temperature range, and realizing the purpose of temperature compensation.

The temperature compensation of a TCXO based on analog circuit, i.e. analog TCXO in prior art is realized through a compensation voltage generated by an analog compensation voltage generation circuit, which has an analog temperature sensor. The temperature compensation can be divided into two ways:

The first temperature compensation of an analog TCXO is based on a thermistor compensation network. As shown in FIG. 1. An open compensation loop is employed in the analog TCXO, using temperature sensitive component such as thermistor to compose a temperature-voltage conversion circuit to obtain a compensation voltage. Through the resistors R1 and R2, the compensation voltage is applied to a varactor diode C1, which is connected in series with the crystal resonator T. The nonlinear frequency drift of the crystal resonator T is compensated by the capacitance change of the varactor diode C1. A detailed description can be found in “Quartz crystal oscillator[M]. Zhao Shengheng. Hunan: Hunan University Press, 1997”. The structure of the analog TCXO in FIG. 1 is simple and easy to realize. However, in order to make the impedance of the thermistor and the capacitance of the varactor diode consistent with the temperature characteristics of the different crystal resonators, it is necessary to select, categorize and replace the resistors and the capacitors of the analog TCXO. Therefore, it is difficult to automatically adjust the temperature compensation, and not conducive to mass production. In addition, the temperature stabilization of the analog TCXO in this way is generally about ±0.5 ppm˜±1 ppm, so the compensation effect is not satisfactory.

The second temperature compensation of an analog TCXO is indirect. The analog TXCO comprises a temperature sensor, a voltage reference circuit, a voltage compensation circuit, a tertiary voltage generator, three coefficient controllers (B0CTR, B1CTR and B3CTR accumulators), a EEPROM memory, a voltage controlled crystal oscillator (VCXO) and an automatic frequency control circuit. See details in “Nemoto K, Sato K I. A 2.5 ppm fully integrated CMOS analog TCXO[C]// Frequency Control Symposium and PDA Exhibition, 2001. Proceedings of the 2001 IEEE International. IEEE, 2001:740-743”. The structure of the analog TCXO in this way is complex, and the analog TCXO can be integrated by large-scale circuit, but the cost is higher than the first way. The temperature compensation of the analog TXCO implemented in this way is also an open-loop compensation, a separate temperature sensor is needed to detect the ambient temperature, it means that the temperature difference and temperature hysteresis effect exist between the sensor and the crystal. So the compensation accuracy is affected.

In sum, the analog TCXO in prior art uses an open-loop compensation architecture, a temperature sensor is needed, and the temperature sensor should be as closer as possible to the crystal resonator on a circuit. However, the resonant wafer of the crystal oscillator is individually enclosed in a confined space, which inevitably produces a temperature hysteresis between the temperature sensor and the resonant wafer, leading that there is no significant breakthrough in the analog TCXO frequency temperature characteristics. Especially for the crystal oscillator with high frequency output, the temperature hysteresis is more obvious, the compensation accuracy of high frequency TCXO is limited seriously.

### SUMMARY OF THE INVENTION

The present invention aims to overcome the deficiencies of the prior art and provides a TCXO based on analogy circuit to avoid the frequency shift of output signal caused by temperature hysteresis, i.e. the discrepancy between the temperature acquired by a temperature sensor and the real temperature of the resonant wafer.

To achieve these objectives, in accordance with the present invention, a TCXO based on analog circuit, comprising:

a VCXO for generating a signal with desired frequency f₀;

wherein further comprising:

a power splitter for dividing the VCXO's current output signal with frequency f=f₀+Δf into two signals, where one signal is used as the output of the TCXO, the other signal is taken as a frequency-voltage conversion signal;

an analog frequency-voltage conversion circuit for receiving the frequency-voltage conversion signal, and converting it, i.e. the VCXO's current output signal with frequency f=f₀+Δf into a voltage signal V(T), which is proportional to the frequency f;

a voltage matching circuit for receiving the voltage signal V(T), then producing the difference between the voltage signal V(T) and a reference voltage signal V_{ref}, i.e. V_{ref}−V(T), and amplifying the difference to obtain a compensation voltage signal ΔV; where the reference voltage signal V_{ref} is the voltage signal converted by the frequency-voltage conversion circuit, when the VCXO is at room temperature 25° C., and generates a signal with desired frequency f₀ by adjusting the control voltage of the VCXO.

a filter for smoothing the compensation voltage signal ΔV, where the smoothed compensation voltage signal ΔV is sent to the voltage control terminal of the VCXO to make the VCXO generate a stable signal with desired frequency f₀.

The objectives of the present invention are realized as follows:

In the present invention, i.e. a TCXO based on analog circuit, a closed-loop compensation architecture is employed to realize the temperature compensation of a crystal oscillator. Firstly, the power splitter divides the VCXO's current output signal with frequency f=f+Δf into two signals, one is used as the output of the TCXO and the other is sent to an analog frequency-voltage conversion circuit. According to the frequency of the VCXO's current output signal, the analog frequency-voltage conversion circuit produces a voltage signal V(T), which is corresponding to current ambient temperature. The difference between the voltage signal V(T) and a reference voltage signal V_{ref} is produced and amplified to obtain a compensation voltage signal ΔV. through a voltage matching circuit, and the compensation voltage signal ΔV is smoothed by a filter, then sent to the voltage control terminal of the VCXO to make the VCXO generate a stable signal with desired frequency f₀, so that the frequency of the VCXO's output signal is compensated, when the ambient temperature is changed.

Comparing to the TCXO based on analog circuit in prior art, the present invention has the following advantageous features:

(1) No temperature sensor is needed. The temperature compensation is performed by converting the frequency of the VCXO's output signal, which is corresponding to current ambient temperature into a corresponding compensation voltage signal. The present invention can overcome the temperature hysteresis problem caused by the asynchronization between the temperature acquired by a temperature sensor and the real temperature of the resonant wafer in the prior art;

(2) A closed-loop feedback compensation architecture is employed in the present invention, the relation between the frequency of the VCXO's current output signal and the compensation voltage signal is established through an analog frequency-voltage conversion circuit, thus the real-time high precision temperature compensation is realized more easily;

(3) It is not necessary to collect the frequency-voltage data of the VCXO at different temperatures in existing TCXO, which reduces the workload;

(4) The compensation process in the present invention is simple, the frequency of the VCXO's output signal is converted into a corresponding voltage signal, and the compensation voltage signal is obtained by comparing the voltage signal with the reference voltage signal. Moreover, the structure of the present invention is also simple, and easy to be integrated and mass-produced;

(5) The present invention can be well applied to crystal oscillators of various frequencies, especially, for the crystal oscillator with high frequency output, which has poor compensation effect in prior art, a better compensation effect can be achieved.

### BRIEF DESCRIPTION OF THE DRAWING

The above and other objectives, features and advantages of the present invention will be more apparent from the following detailed description taken in conjunction with the accompanying drawings, in which:

FIG. 1 is a diagram of a TCXO based on a thermistor compensation network in prior art;

FIG. 2 is a diagram of a TCXO based on analog circuit according to one embodiment of the present invention;

FIG. 3 is a diagram of the TCXO shown in FIG. 2 according to one embodiment of the present invention.

### DETAILED DESCRIPTION OF THE PREFERRED EMBODIMENT

Hereinafter, preferred embodiments of the present invention will be described with reference to the accompanying drawings. It should be noted that the similar modules are designated by similar reference numerals although they are illustrated in different drawings. Also, in the following description, a detailed description of known functions and configurations incorporated herein will be omitted when it may obscure the subject matter of the present invention.

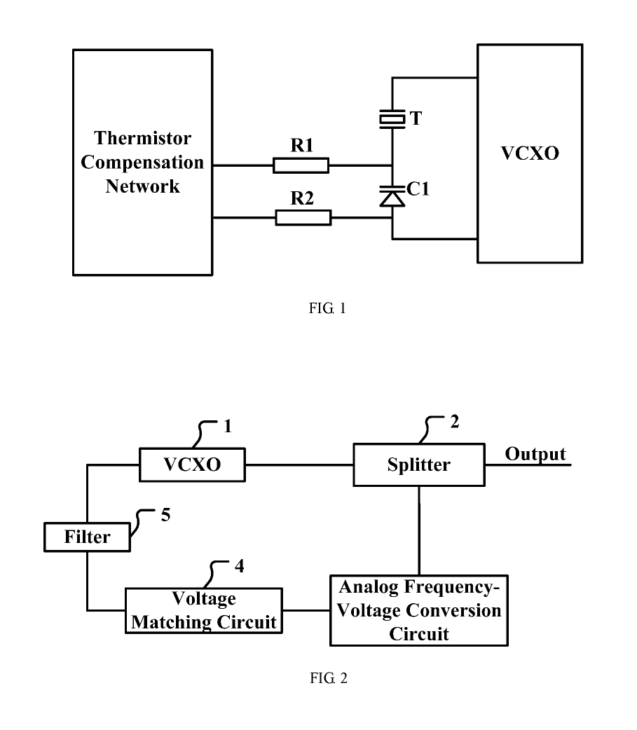

FIG. 2 is a diagram of a TCXO based on analog circuit according to one embodiment of the present invention.

In one embodiment, as shown in FIG. 2, the TCXO based on analog circuit comprises a voltage controlled crystal oscillator, i.e. VCXO 1, a power splitter 2, an analog frequency-voltage conversion circuit 3, a voltage matching circuit 4 and a filter 5.

The power splitter 2 divides the VCXO's current output signal with frequency f=f₀+Δf into two signals, one signal is used as the output of the TCXO, the other signal is taken as a frequency-voltage conversion signal and sent to the analog frequency-voltage conversion circuit 3, where the Δf is the frequency shift of the crystal resonator in the VCXO 1, which is caused by ambient temperature's change.

The analog frequency-voltage conversion circuit 3 receives the frequency-voltage conversion signal, and converts it, i.e. the VCXO's current output signal with frequency f=f₀+Δf into a voltage signal V(T), which is proportional to the frequency f, then sends the voltage signal V(T) to the voltage matching circuit 4.

The voltage matching circuit 4 receives the voltage signal V(T), then produces the difference between the voltage signal V(T) and a reference voltage signal V_{ref}, i.e. V_{ref}−V(T), and amplifies the difference to obtain a compensation voltage signal ΔV. Where the reference voltage signal V_{ref} is the voltage signal converted by the frequency-voltage conversion circuit 3, when the VCXO 1 is at room temperature 25° C., and generates a signal with desired frequency f₀ by adjusting the control voltage of the VCXO 1.

The filter 5 smoothes the compensation voltage signal ΔV, where the smoothed compensation voltage signal ΔV is sent to the voltage control terminal of the VCXO 1 to make the VCXO 1 generate a stable signal with desired frequency f₀.

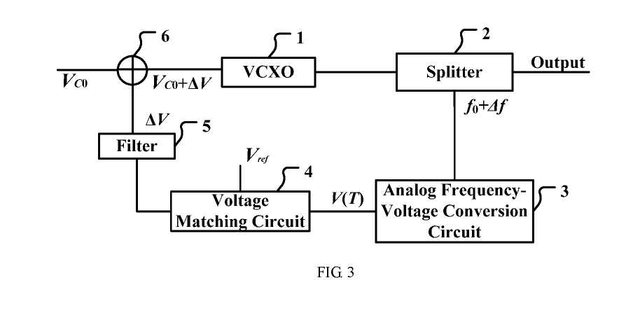

FIG. 3 is a diagram of the TCXO shown in FIG. 2 according to one embodiment of the present invention.

In one embodiment, as shown in FIG. 3, the TCXO 1 based on analog circuit further comprises an adder 6 for adding the filtered compensation voltage signal ΔV to the control voltage VC₀, and obtaining the control voltage VC=VC₀+ΔV. The control voltage VC is applied to the voltage control terminal of the VCXO 1 to make the VCXO 1 generate a stable signal with desired frequency f₀, so that the frequency of the VCXO's output signal is compensated, when the ambient temperature is changed.

In a process of implementing the present invention, the VCXO 1 generates a signal with desired frequency f₀ by adjusting the control voltage of the VCXO 1 at room temperature 25° C., then, the signal with desired frequency f₀ is sent to the frequency-voltage conversion circuit 3 and converted into a voltage signal. The converted voltage signal is taken as the reference voltage signal V_{ref} of the voltage matching circuit 4.

When the TCXO based on analog circuit is in operation at temperature T, the VCXO 1 generates an output signal with frequency f₀+Δf under the control voltage VC₀, which is caused by ambient temperature's change, i.e. the frequency of the VCXO's current output signal is f=f₀+Δf. the VCXO's current output signal is divided into two signals, one signal is used as the output of the TCXO, the other signal is taken as a frequency-voltage conversion signal and sent to the analog frequency-voltage conversion circuit 3.

The analog frequency-voltage conversion circuit 3 receives the frequency-voltage conversion signal, and converts it, i.e. the VCXO's current output signal with frequency f=f₀+Δf into a voltage signal V(T), which is proportional to the frequency f, then sends the voltage signal V(T) to the voltage matching circuit 4. The voltage matching circuit 4 receives the voltage signal V(T), then produces the difference between the voltage signal V(T) and a reference voltage signal V_{ref}, i.e. V_{ref}−V(T), and amplifies the difference to obtain a compensation voltage signal ΔV, the compensation voltage signal ΔV is sent to the filter 5.

The compensation voltage signal ΔV is smoothed by the filter 5, and sent to the adder 6. In the adder 6, the smoothed compensation voltage signal ΔV is added to the control voltage VC₀, and the compensated control voltage VC=VC₀+ΔV is obtained. The control voltage VC is applied to the voltage control terminal of the VCXO 1 to make the VCXO 1 generate a stable signal with desired frequency f₀, so that the frequency of the VCXO's output signal is compensated, when the ambient temperature is changed.

While illustrative embodiments of the invention have been described above, it is, of course, understand that various modifications will be apparent to those of ordinary skill in the art. Such modifications are within the spirit and scope of the invention, which is limited and defined only by the appended claims.

What is claimed is:

1. A temperature-compensated crystal oscillator based on analog circuit, comprising:
a VCXO for generating a signal with desired frequency f₀;
wherein further comprising:
a power splitter for dividing the VCXO's current output signal with frequency f=f₀+Δf into two signals, where one signal is used as the output of the TCXO, the other signal is taken as a frequency-voltage conversion signal;
an analog frequency-voltage conversion circuit for receiving the frequency-voltage conversion signal, and converting it, i.e. the VCXO's current output signal with frequency f=f₀+Δf into a voltage signal V(T), which is proportional to the frequency f;
a voltage matching circuit for receiving the voltage signal V(T), then producing the difference between the voltage signal V(T) and a reference voltage signal V_{ref}, i.e. V_{ref}−V(T), and amplifying the difference to obtain a compensation voltage signal ΔV; where the reference voltage signal V_{ref} is the voltage signal converted by the frequency-voltage conversion circuit, when the VCXO is at room temperature 25° C., and generates a signal with desired frequency f₀ by adjusting the control voltage of the VCXO;
a filter for smoothing the compensation voltage signal ΔV, where the smoothed compensation voltage signal ΔV is sent to the voltage control terminal of the VCXO to make the VCXO generate a stable signal with desired frequency f₀.

2. A temperature-compensated crystal oscillator based on analog circuit of claim 1, wherein further comprising an adder for adding the filtered compensation voltage signal ΔV to the control voltage VC₀, and obtaining the control voltage VC=VC₀+ΔV; where the control voltage VC is applied to the voltage control terminal of the VCXO to make the VCXO generate a stable signal with desired frequency f₀, so that the frequency of the VCXO's output signal is compensated, when the ambient temperature is changed.
